(19) United States
(12) Patent Application Publication
(10) Pub. No.: US 2025/0311217 A1
(43) Pub. Date: Oct. 2, 2025

(54) Memory Circuitry And Methods Used In Forming Memory Circuitry

(71) Applicant: Micron Technology, Inc., Boise, ID (US)

(72) Inventor: Darwin A. Clampitt, Wilder, ID (US)

(73) Assignee: Micron Technology, Inc., Boise, ID (US)

(21) Appl. No.: 19/045,017

(22) Filed: Feb. 4, 2025

Related U.S. Application Data
(60) Provisional application No. 63/570,937, filed on Mar. 28, 2024.

(51) Int. Cl. H10B 43/27; G11C 16/04; H10B 41/10; H10B 41/27; H10B 41/35; H10B 43/10; H10B 43/35

(52) U.S. Cl. CPC H10B 43/27; G11C 16/0483; H10B 41/10; H10B 41/27; H10B 41/35; H10B 43/10; H10B 43/35

(57) ABSTRACT

Memory circuitry comprises a stack comprising vertically-alternating insulative tiers and conductive tiers, the stack comprising laterally-spaced memory blocks comprising sub-blocks in an upper portion thereof. A conductive-material tier is in the upper portions and conductive material thereof extends downwardly therefrom. Select gates of select-gate transistors are in individual of the sub-blocks operatively alongside channel material of the select-gate transistors. A gate insulator layer is laterally-between the select gates and the channel material of the select-gate transistors. The gate insulator layer extends laterally to be vertically-between the channel material and the select gates directly under the select gates. Other embodiments, including method, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region there-between.

A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate.

Flash memory is one type of memory and has numerous uses in modern computers and devices. For instance, modern personal computers may have BIOS stored on a flash memory chip. As another example, it is becoming increasingly common for computers and other devices to utilize flash memory in solid state drives to replace conventional hard drives. As yet another example, flash memory is popular in wireless electronic devices because it enables manufacturers to support new communication protocols as they become standardized, and to provide the ability to remotely upgrade the devices for enhanced features.

NAND may be a basic architecture of integrated flash memory. A NAND cell unit comprises at least one selecting device coupled in series to a serial combination of memory cells (with the serial combination commonly being referred to as a NAND string). NAND architecture may be configured in a three-dimensional arrangement comprising vertically-stacked memory cells individually comprising a reversibly programmable vertical transistor. Control or other circuitry may be formed below the vertically-stacked memory cells. Other volatile or non-volatile memory array architectures may also comprise vertically-stacked memory cells that individually comprise a transistor.

Memory arrays may be arranged in memory pages, memory blocks and partial blocks (e.g., sub-blocks), and memory planes. The memory blocks may at least in part define longitudinal outlines of individual wordlines in individual wordline tiers of vertically-stacked memory cells. Connections to these wordlines may occur in a so-called “stair-step structure” at an end or edge of an array of the vertically-stacked memory cells. The stair-step structure includes individual “stairs” (alternately termed “steps” or “stair-steps”) that define contact regions of the individual wordlines upon which elevationally-extending conductive vias contact to provide electrical access to the wordlines.

### BRIEF DESCRIPTION OF THE DRAWINGS

FIGS. 1-5 are diagrammatic cross-sectional views of portions of a construction that will comprise memory circuitry in accordance with an embodiment of the invention.

FIGS. 6-33 are diagrammatic sequential sectional and/or enlarged views of the construction of FIGS. 1-5, or portions thereof or alternate and/or additional embodiments, in process in accordance with some embodiments of the invention.

### DETAILED DESCRIPTION OF EXAMPLE EMBODIMENTS

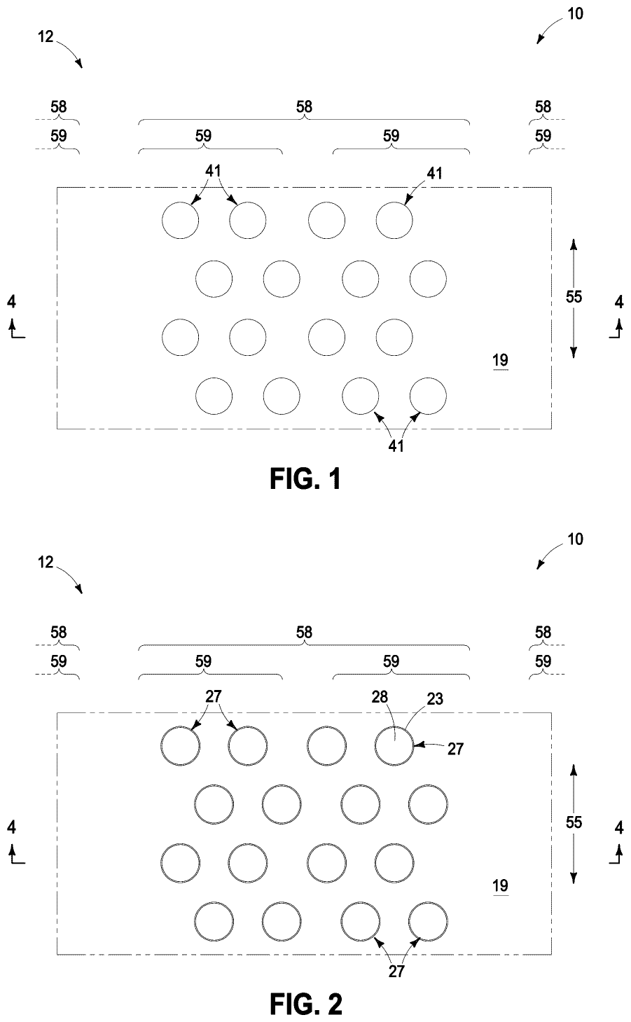

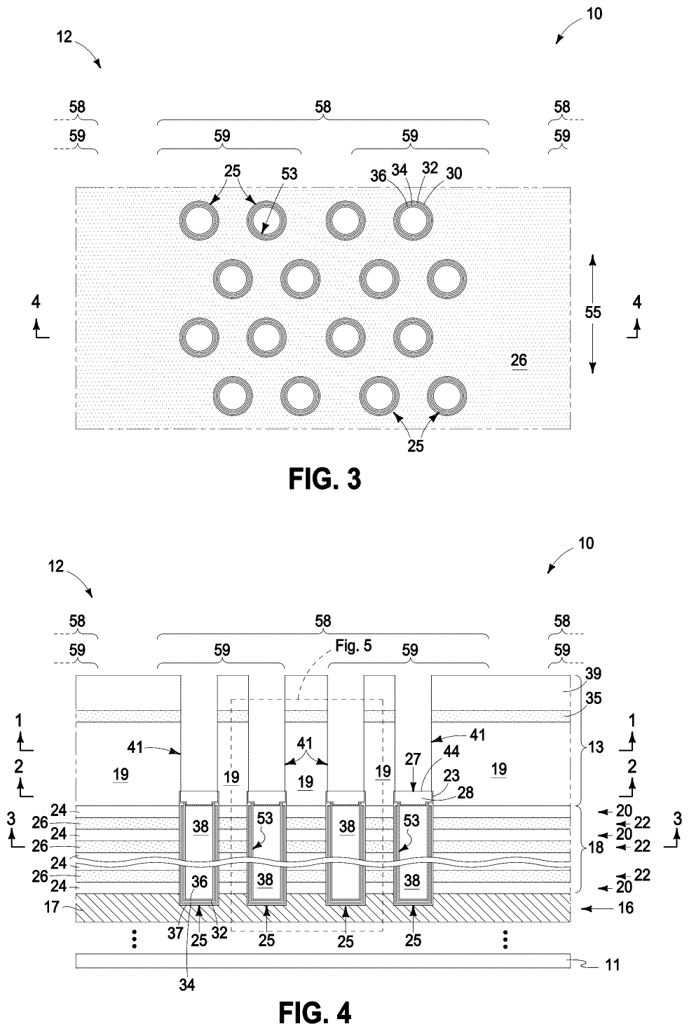

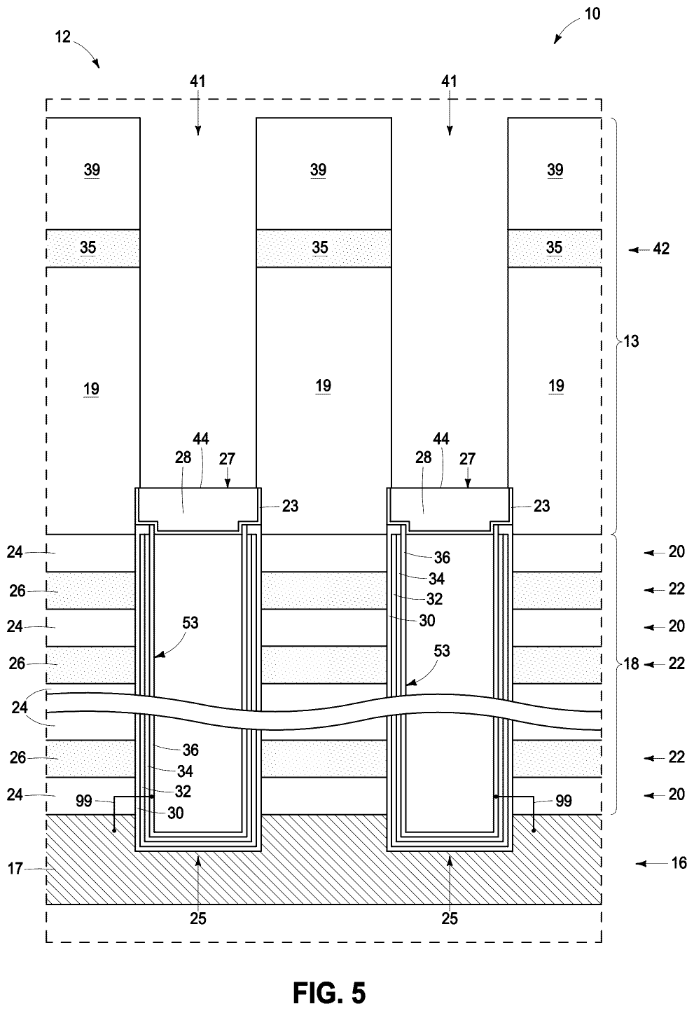

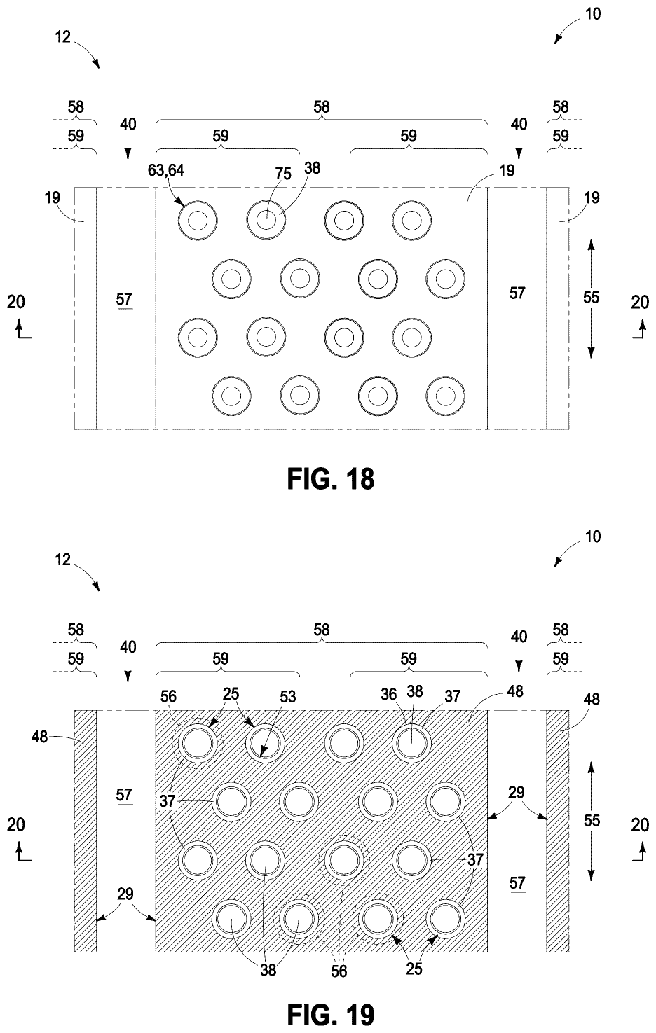

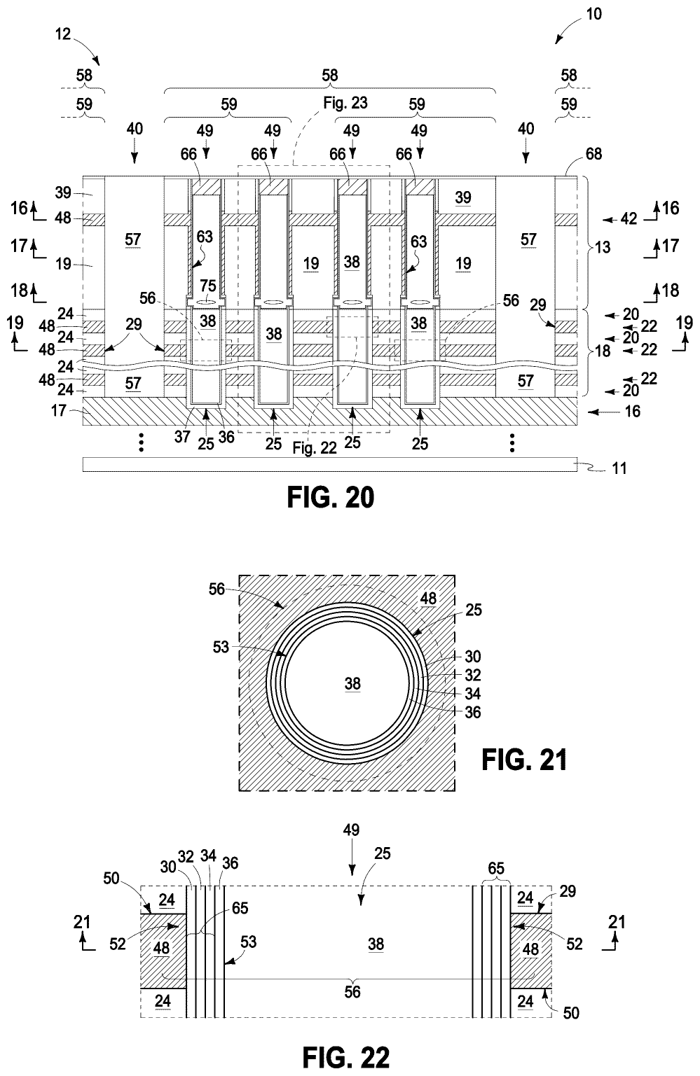

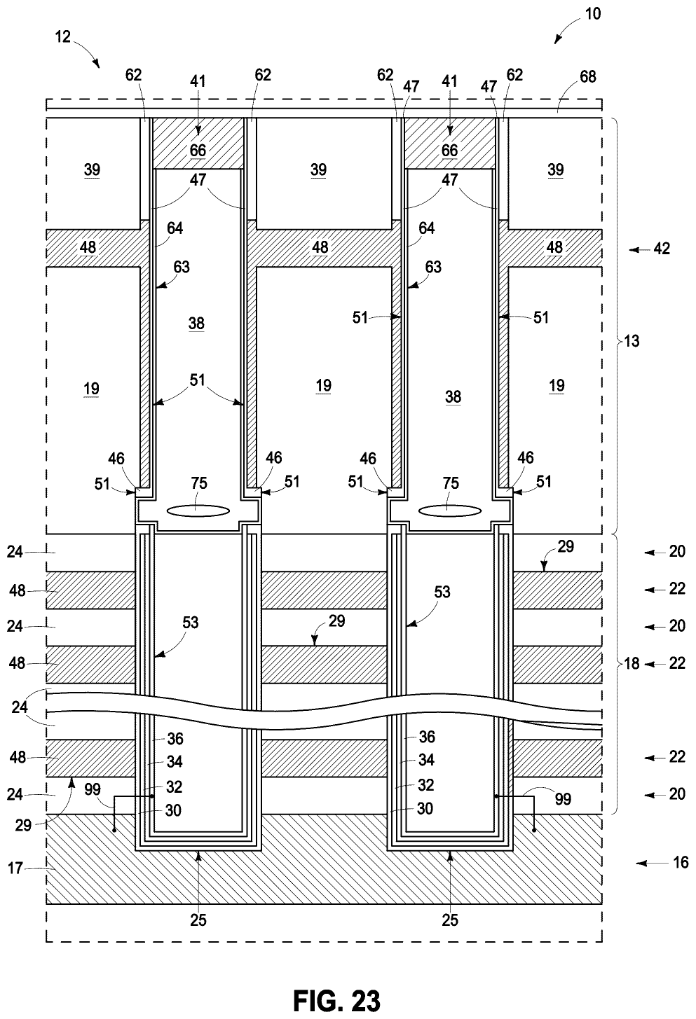

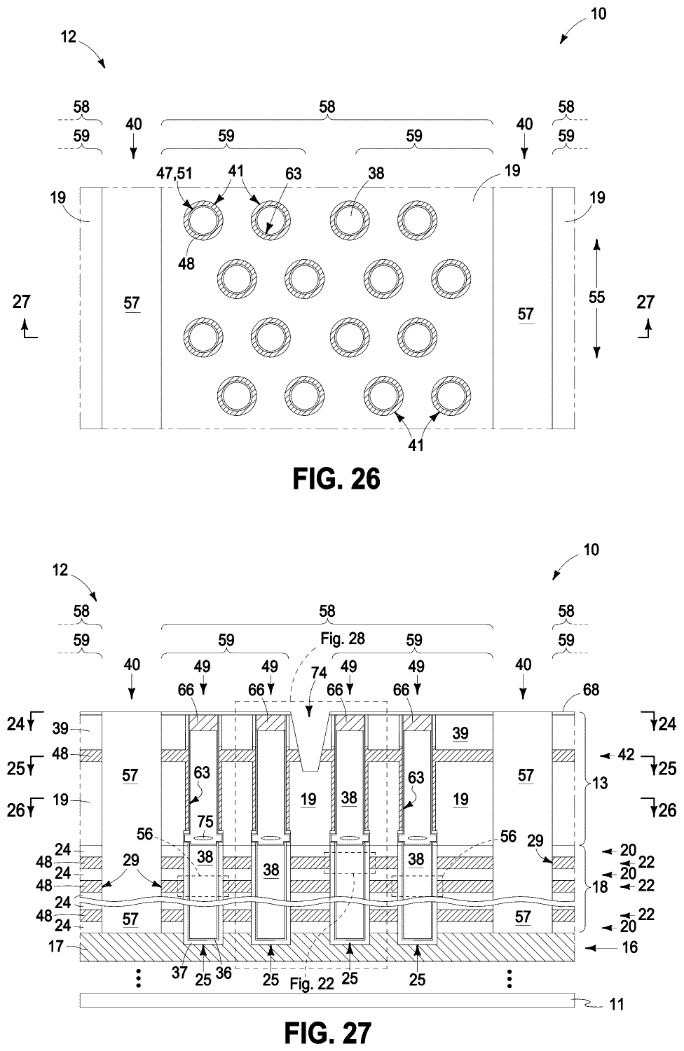

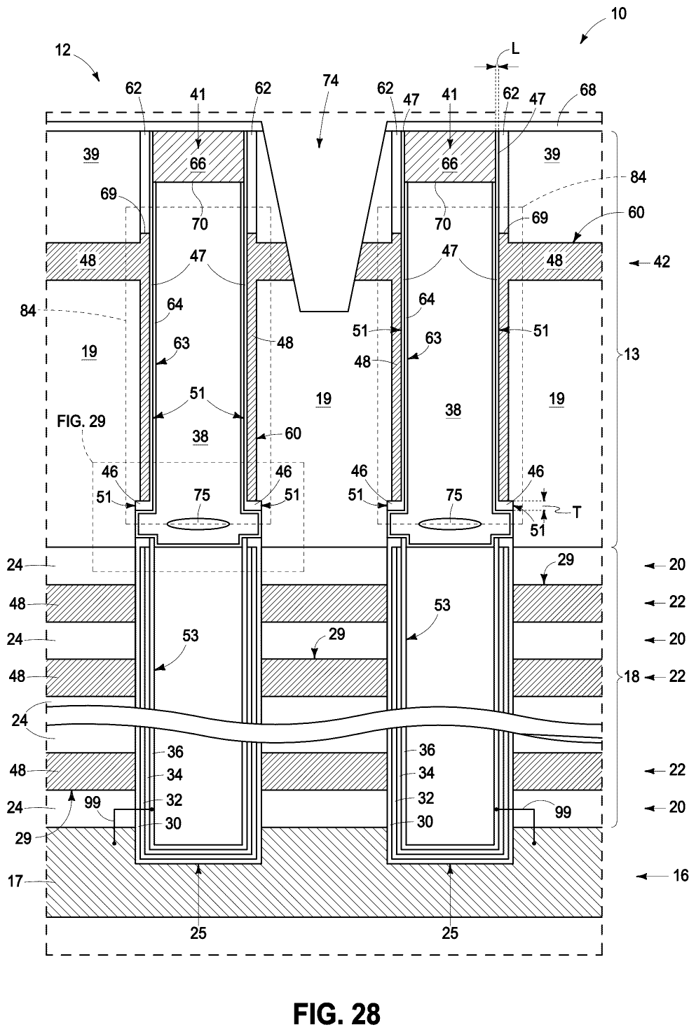

Embodiments of the invention encompass methods used in forming memory circuitry, for example that comprise an array of NAND or other memory cells that may have at least some peripheral control circuitry under the array (e.g., CMOS-under-array). Embodiments of the invention encompass so-called “gate-last” or “replacement-gate” processing, so-called “gate-first” processing, and other processing whether existing or future-developed independent of when transistor gates are formed. Embodiments of the invention also encompass memory circuitry comprising strings of memory cells (e.g., NAND architecture) independent of method of manufacture. Example embodiments are described with reference to FIGS. 1-33.

FIGS. 1-5 show an example construction 10 having an array 12 in which strings of transistors and/or memory cells will be formed. Example construction 10 includes a base substrate 11 having any one or more of conductive/conductor/conducting, semiconductive/semiconductor/semiconducting, or insulative/insulator/insulating (i.e., electrically herein) materials. Various materials have been formed elevationally over base substrate 11. Materials may be aside, elevationally inward, or elevationally outward of the FIGS. 1-5-depicted materials. For example, other partially or wholly fabricated components of integrated circuitry may be provided somewhere above, about, or within base substrate 11. Control and/or other peripheral circuitry for operating components within an array (e.g., array 12) of elevationally-extending strings of memory cells may also be fabricated and may or may not be wholly or partially within an array or sub-array. Further, multiple sub-arrays may also be fabricated and operated independently, in tandem, or otherwise relative one another. In this document, a “sub-array” may also be considered as an array.

A conductor tier 16 comprising conductor material 17 (e.g., WSiₓ under conductively-doped polysilicon) is above substrate 11. Conductor tier 16 may comprise part of control circuitry (e.g., peripheral-under-array circuitry and/or a common source line or plate) used to control read and write access to the transistors and/or memory cells in array 12. A stack 18 comprising vertically-alternating first/conductive tiers 22 and second/insulative tiers 20 has been formed above conductor tier 16. Example thickness for each of tiers 20 and 22 is 20 to 60 nanometers. The example uppermost tier 20 may be thicker/thickest compared to one or more other tiers 20 and/or 22. Only a small number of tiers 20 and 22 is shown, with more likely stack 18 comprising dozens, a hundred or more, etc. of tiers 20 and 22. Other circuitry that may or may not be part of peripheral and/or control circuitry may be between conductor tier 16 and stack 18. For example, multiple vertically-alternating tiers of conductive material and insulative material of such circuitry may be below a lowest of the conductive tiers 22 and/or above an uppermost of the conductive tiers 22. For example, one or more select-gate tiers (not shown) may be between conductor tier 16 and the lowest conductive tier 22. Conductive tiers 22 may not be conductive at this point of processing, for example if “gate-last”/“replacement gate”, and insulative tiers 20 may not be insulative at this point of processing. Regardless, in some embodiments conductive tiers 22 are referred to as first tiers 22 and insulative tiers 20 are referred to as second tiers 20, and which are of different compositions relative one another. Example insulative/second tiers 20 comprise insulative material 24 (e.g., silicon dioxide and/or other material that may be of one or more composition(s)). Example conductive/first tiers 22 comprise sacrificial material 26 (e.g., silicon nitride) in the example gate-last processing. Such would comprise conductive material (not shown) in so-called gate-first processing.

A select-gate region 13 is directly above stack 18.

Channel openings 25 have been formed (e.g., by etching) through vertically-alternating tiers 20 and 22 to conductor tier 16. Channel openings 25 may taper radially-inward and/or radially-outward (not shown) moving deeper in stack 18. In some embodiments, channel openings 25 may go into conductor material 17 of conductor tier 16 as shown or may stop there-atop (not shown). Alternately, as an example, channel openings 25 may stop atop or within the lowest second-material tier 20. A reason for extending channel openings 25 at least to conductor material 17 of conductor tier 16 is to assure direct electrical coupling of channel material to conductor tier 16 without using alternative processing and structure to do so when such a connection is desired and/or to provide an anchoring effect to material that is within channel openings 25. Etch-stop material (not shown) may be within or atop conductor material 17 of conductor tier 16 to facilitate stopping of the etching of channel openings 25 relative to conductor tier 16 when such is desired. Such etch-stop material may be sacrificial or non-sacrificial. By way of example, for brevity, and for clarity only, channel openings 25 are shown as being arranged in groups or columns of staggered rows of four openings 25 per row and being arrayed in laterally-spaced memory-block regions 58 that will comprise laterally-spaced memory blocks 58 in a finished-circuitry construction. Memory-block regions 58 and resultant memory blocks 58 may be considered as being longitudinally elongated and oriented, for example along a first direction 55. Only one full memory-block region 58 is shown due to scale (hereafter referred to as memory block 58). Any alternate existing or future-developed arrangement and construction may be used. Select-gate region 13 comprises sub-blocks 59 in individual memory blocks 58. Only two sub-blocks 59 are shown in a memory block 58 although more sub-blocks may be in each memory block and not all memory blocks need have the same number of sub-blocks. Sub-blocks 59 and/or memory blocks 58 may not be discernable at this point of processing.

Transistor channel material may be formed in the individual channel openings elevationally along the insulative tiers and the conductive tiers, thus comprising individual channel-material strings, which is directly electrically coupled with conductive material in the conductor tier. Individual memory cells of the example memory array being formed may comprise a gate region (e.g., a control-gate region) and a memory structure laterally between the gate region and the channel material. In one such embodiment, the memory structure is formed to comprise a charge-blocking region, storage material (e.g., charge-storage material), and an insulative charge-passage material. The storage material (e.g., floating gate material such as doped or undoped silicon or charge-trapping material such as silicon nitride, metal dots, etc.) of the individual memory cells is elevationally along individual of the charge-blocking regions. The insulative charge-passage material (e.g., a band gap-engineered structure having nitrogen-containing material [e.g., silicon nitride] sandwiched between two insulator oxides [e.g., silicon dioxide]) is laterally between the channel material and the storage material.

The figures show one embodiment wherein charge-blocking material 30, storage material 32, and charge-passage material 34 have been formed in individual channel openings 25 elevationally along vertically-alternating tiers 20 and 22. Transistor materials 30, 32, and 34 (e.g., memory-cell materials) may be formed by, for example, deposition of respective thin layers thereof over stack 18 and within individual channel openings 25 followed by planarizing such back at least to a top surface of stack 18 as shown.

First channel material 36 has also been formed in channel openings 25 elevationally along vertically-alternating tiers 20 and 22 and comprises individual first channel-material strings 53 in memory blocks 58, and which in one embodiment having memory-cell materials (e.g., 30, 32, and 34) there-along and with insulative material 24 in second-material tiers 20 being horizontally-between immediately-adjacent first channel-material strings 53. Materials 30, 32, 34, and 36 are collectively shown as and only designated as material 37 in some figures due to scale. First channel-material strings 53 extend upwardly into select-gate region 13. Example first channel materials 36 include appropriately-doped crystalline semiconductor material, such as one or more silicon, germanium, and so-called III/V semiconductor materials (e.g., GaAs, InP, GaP, and GaN). Example thickness for each of materials 30, 32, 34, and 36 is 25 to 100 Angstroms. Punch etching may be conducted (not shown) to remove materials 30, 32, and 34 from the bases of channel openings 25 to expose conductor tier 16 such that first channel material 36 (first channel-material string 53) is directly electrically coupled with conductor material 17 of conductor tier 16. Such punch etching may occur separately (not shown) with respect to each of materials 30, 32, and 34 or may occur collectively with respect to all after deposition of material 34 (not shown). Alternately, and by way of example only, no punch etching may be conducted (as shown) and first channel material 36 may be directly electrically coupled with conductor material 17 of conductor tier 16, for example by a separate conductive interconnect 99. Such is shown schematically and is likely formed subsequently, for example as shown in U.S. Patent Publication Nos. 2023/0062084 and/or 2023/0055422. Channel openings 25 are shown as comprising a radially-central solid dielectric material 38 (e.g., spin-on-dielectric, silicon dioxide, and/or silicon nitride). Alternately, and by way of example only, the radially-central portion within channel openings 25 may include void space(s) (not shown). Dielectric material 38 may be vertically recessed as shown. First channel material 36 below the top of recessed dielectric material 38 is suitably doped (e.g., during its deposition; or may be undoped) to be of desired semi-conductivity to function as a transistor channel. If vertically-recessing dielectric material 38, first channel material 36 may be suitably doped to be conductive above dielectric material 38.

In one embodiment and as shown, sacrificial masses 27 have been formed atop first channel-material strings 53. Example such masses comprise a sacrificial liner 23 (e.g., silicon nitride) having a sacrificial core 28 (e.g., polysilicon) radially-inward thereof. Insulative material 19 (e.g., silicon dioxide or silicon nitride atop a thin layer of silicon dioxide) is in select-gate region 13 above first channel-material strings 53 (e.g., atop and aside sacrificial masses 27). In one embodiment and as shown, sacrifice material 35 of a sacrifice-material tier 42 has been formed in select-gate region 13 atop insulative material 19 and extends laterally-between immediately-laterally-adjacent sub-blocks 59. Sacrificial material 26 and sacrifice material 35 are ideally of the same composition relative one another. Insulator material 39 (e.g., silicon dioxide) is ideally formed above sacrifice material 35 as shown. An opening 41 has been formed to extend through insulative material 19 (and through materials 39 and 35 when present) to individual sacrificial masses 27. In one such embodiment and as shown, opening 41 at a top surface 44 of individual sacrificial masses 27 is smaller in area than area of said top surface 44.

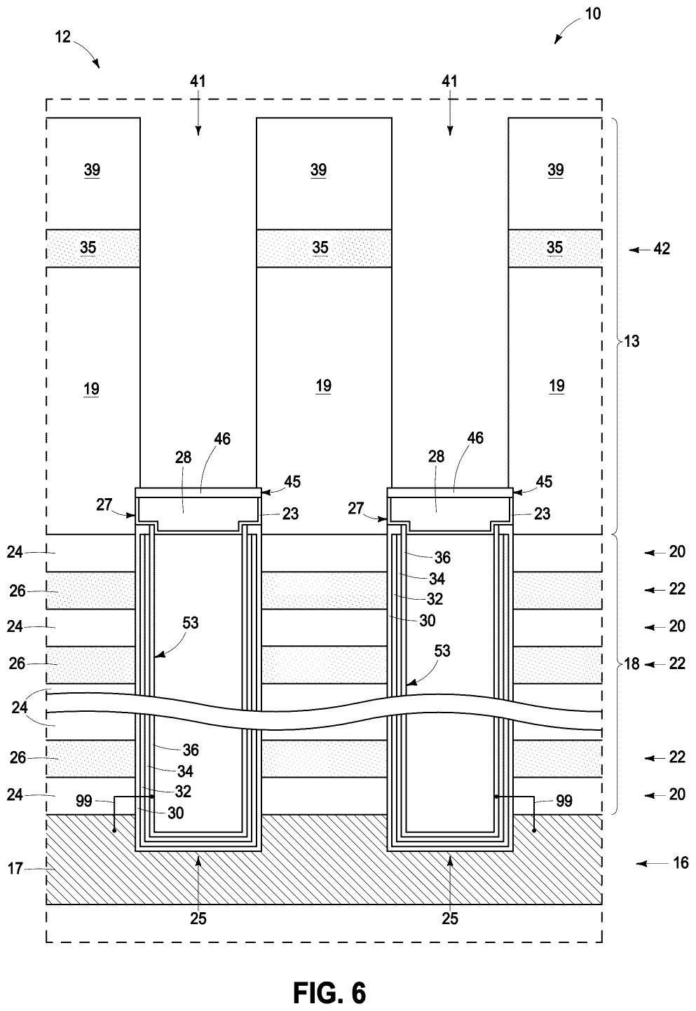

Referring to FIG. 6, and in one embodiment, a top region 45 (and only a top region) of individual sacrificial masses 27 has been oxidized (e.g., by exposure to H₂O, O₂, and/or O₃) to form a gate oxide 46 there-across (e.g., silicon dioxide).

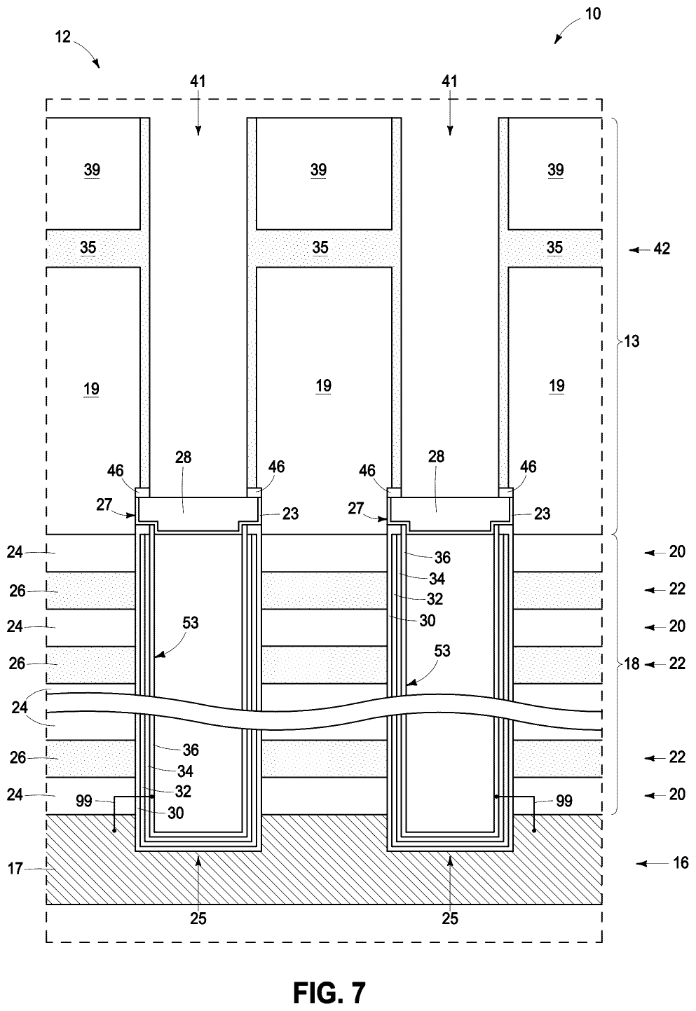

Referring to FIG. 7, sacrifice material (e.g., 35, the same composition as that in sacrifice-material tier 42) has been formed (e.g., in openings 41) to extend downwardly from sacrifice-material tier 42 to below sacrifice-material tier 42. Example sacrifice material 35 may be deposited as a layer, followed by spacer-like etch thereof to remove such from largely being over horizontal surfaces. Regardless, gate oxide 46 has subsequently been etched through (e.g., ideally anisotropically as shown).

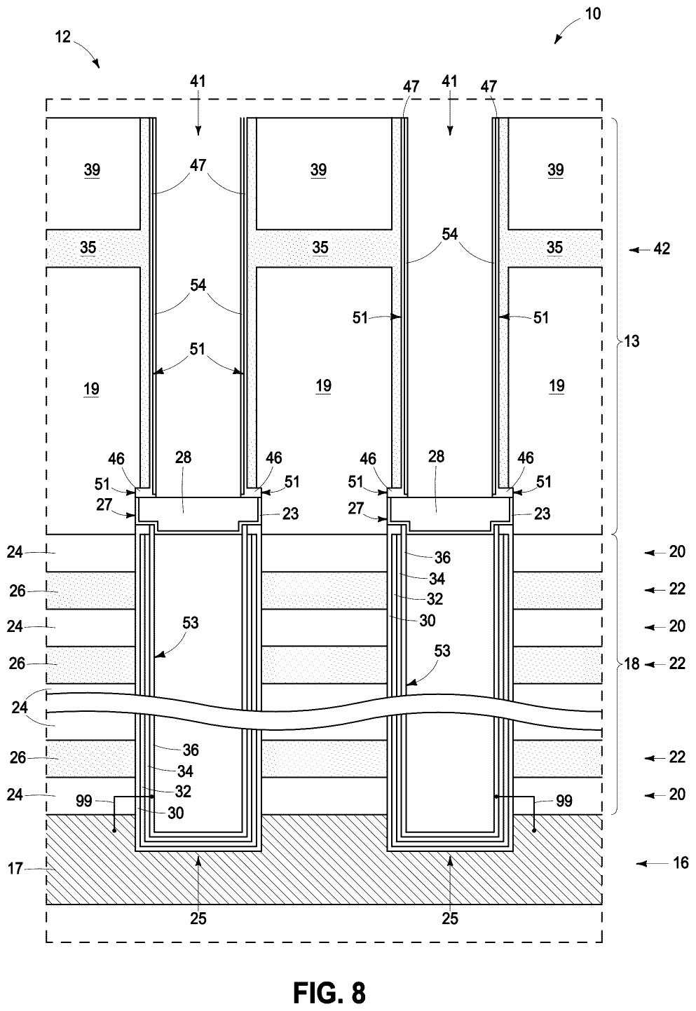

Referring to FIG. 8, a gate insulator material 47 has been formed in opening 41 directly against gate oxide 46. Gate insulator material 47 and gate oxide 46 comprise a continuous gate insulator layer 51. A protective layer 54 (e.g., polysilicon) may be deposited over gate insulator material 47, then both spacer-etched to remove such from largely being over horizontal surfaces (e.g., regardless, exposing tops of sacrifice material 35).

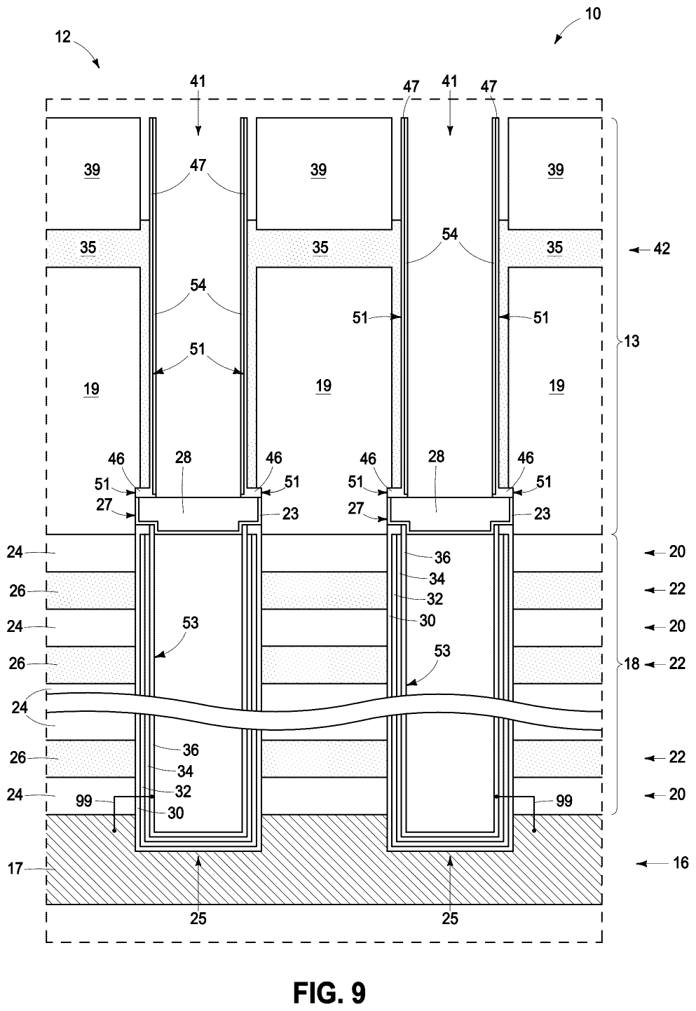

Referring to FIG. 9, sacrifice material 35 has been wet-etched back (e.g., using H₃PO₄ if silicon nitride).

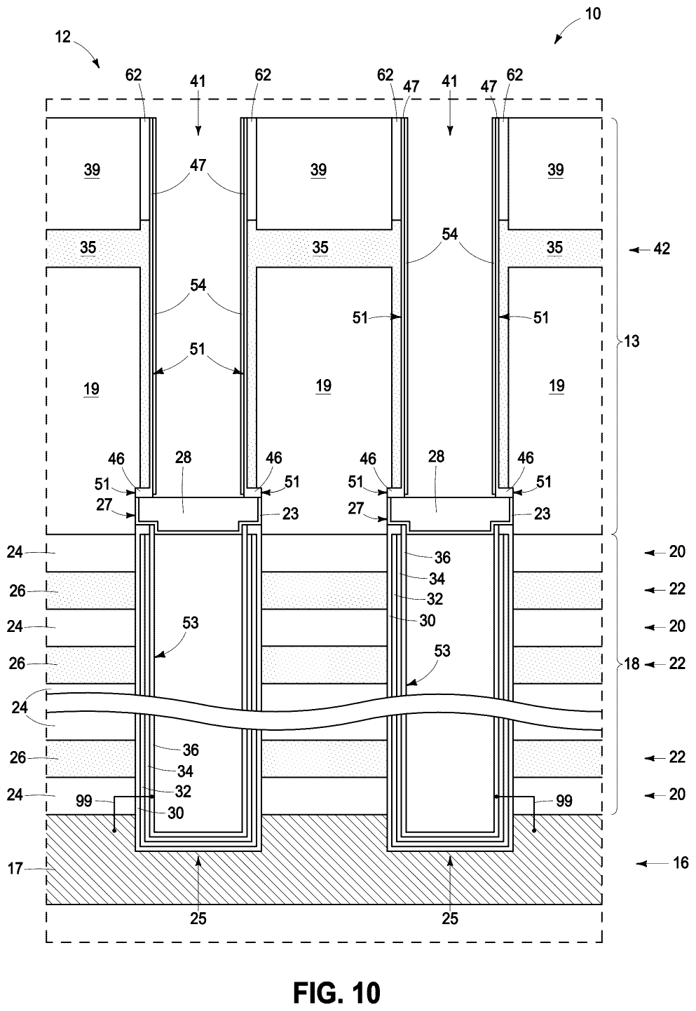

Referring to FIG. 10, insulating material 62 (e.g., silicon dioxide) has been formed to cover sacrifice material 35 that was vertically-recessed-back in FIG. 9. Insulating material 62 has then been etched back (e.g., isotropically) to remain covering sacrifice material 35 and expose protective layer 54 and sacrificial masses 27.

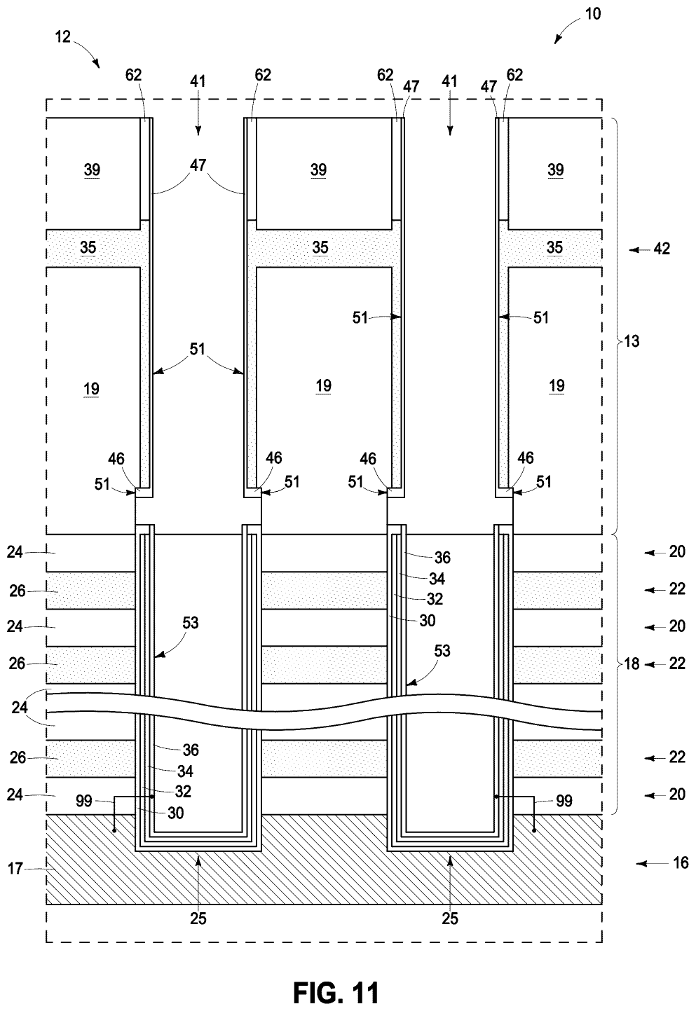

Referring to FIG. 11, protectively layer 54 (not shown) and sacrificial core 28 (not shown) have been etched selectively relative to sacrificial liner 23 (not shown; e.g., using tetramethyl ammonium hydroxide where layer 54 and core 28 comprise polysilicon and liner 23 comprises silicon nitride). This has been followed by etching sacrificial liner 23 (not shown). Such is but one example in one embodiment of removing remaining volume of sacrificial masses 27 (such thereby no longer being shown).

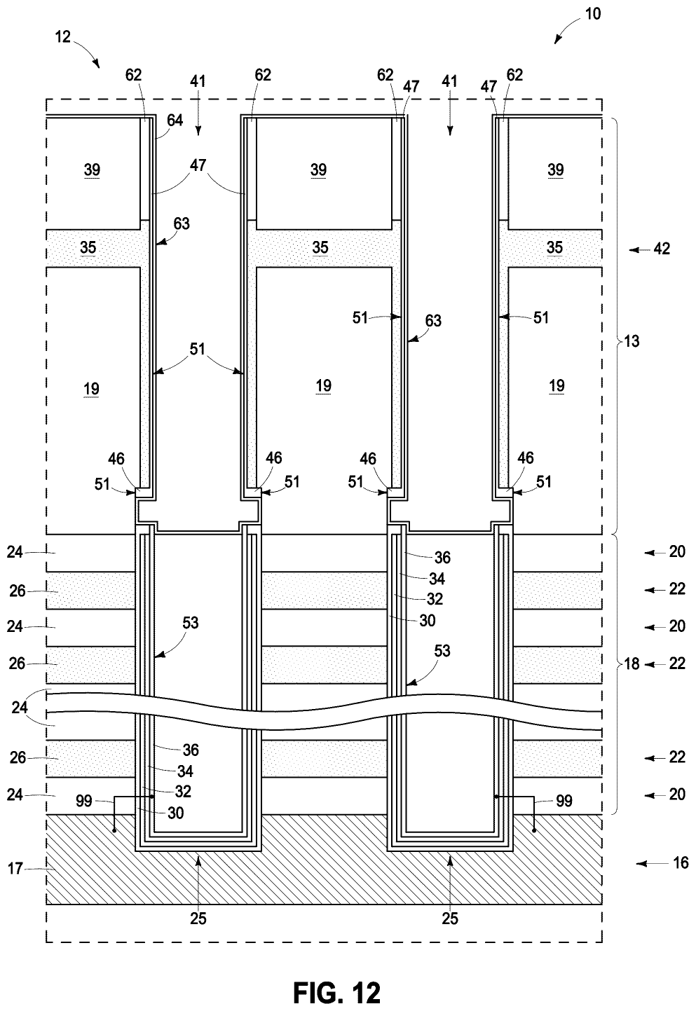

Referring to FIG. 12, a second channel-material string 63 has been formed in opening 41 laterally-inward of gate insulator material 47 and that is directly electrically coupled to first channel-material string 53 there-below. Example second channel-material strings 63 comprise second channel material 64 that may be of the same or different composition as/from that of first channel material 36. In one embodiment and as shown, sacrifice material 35 extends downwardly from sacrifice-material tier 42 to below sacrifice-material tier 42 alongside second channel material 64 of second channel-material strings 63 that are in select-gate region 13, with individual second channel-material strings 63 being directly electrically coupled to the first channel-material string 53 there-below.

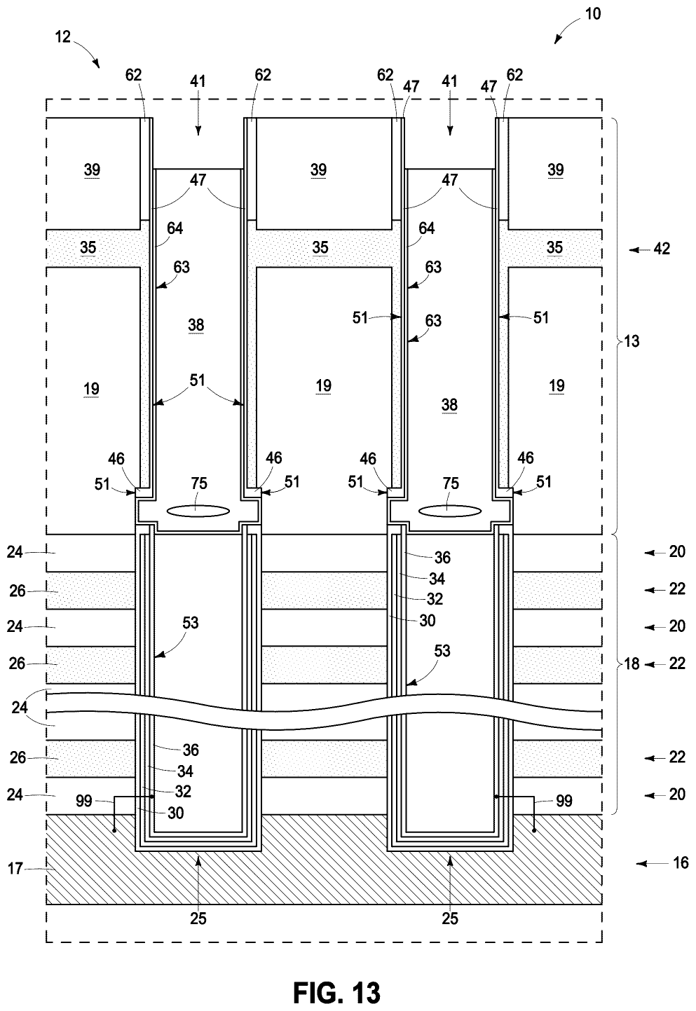

Referring to FIG. 13, a radially-central solid dielectric material 38 has been formed in opening 41. A void-space 75 may form therein, as shown. Dielectric material 38 has then been vertically recessed and second channel-material strings 63 have been etched back and the tops thereof suitably conductively-doped to be conductive. Second channel material 64 is shown as having optionally been etched back from being atop construction 10.

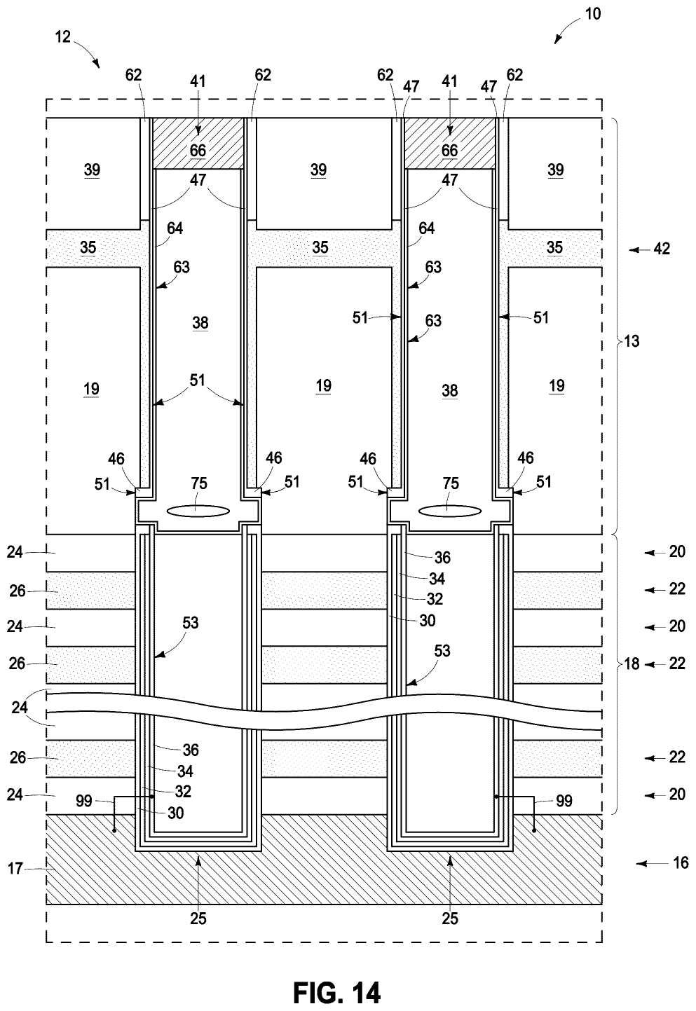

Referring to FIG. 14, and in one embodiment, conducting metal material 66 (e.g., a Ti, TiN, W composite) has been formed in select-gate region 13 directly against second channel material 64.

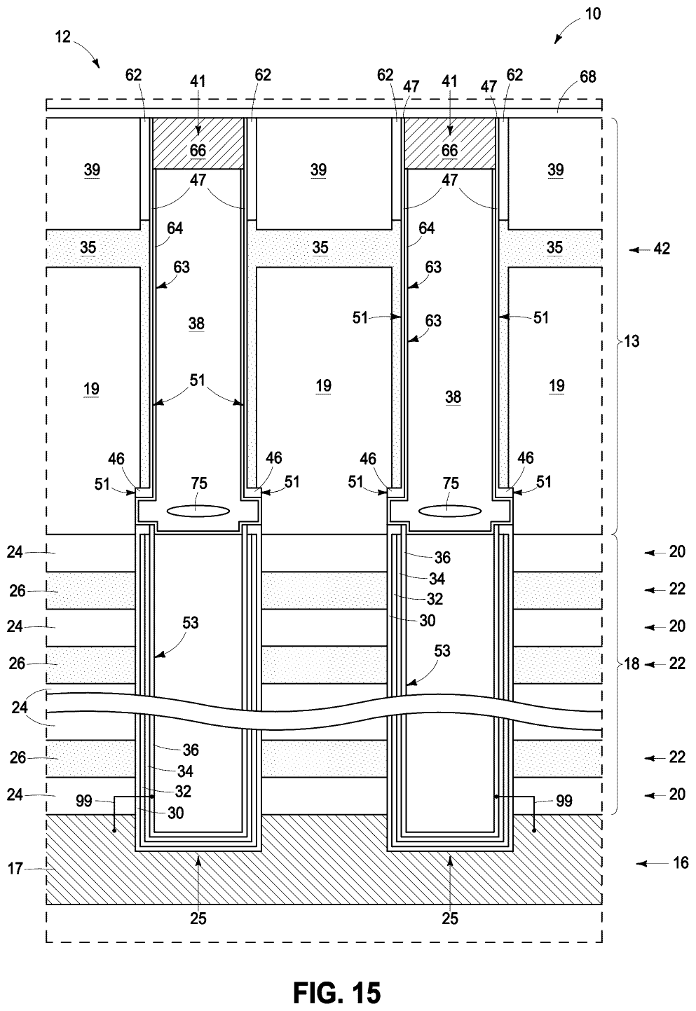

Referring to FIG. 15, and in one such latter embodiment, conducting metal material 66 has been covered with a protective cover 68 (e.g., silicon dioxide).

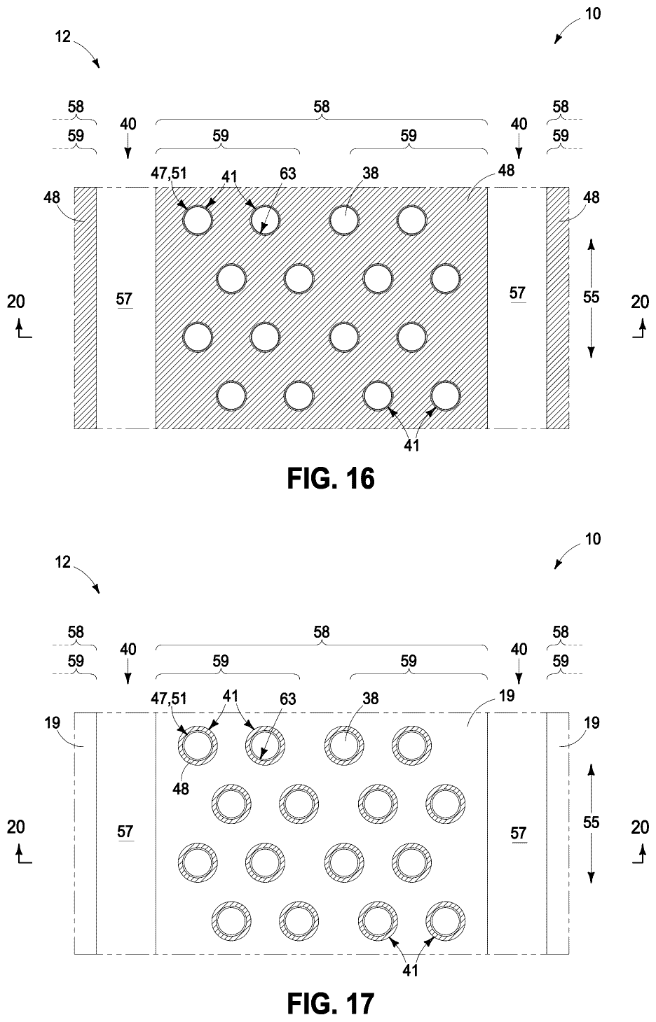

Referring to FIGS. 16-23, horizontally-elongated trenches 40 have been formed (e.g., by anisotropic etching) between immediately-laterally-adjacent memory blocks 58. Trenches 40 may be wider than channel openings 25 (e.g., 3 to 10 times wider). Trenches 40 may have respective bottoms that are directly against conductor material 17 (e.g., atop or within) of conductor tier 16 (as shown) or may have respective bottoms that are above conductor material 17 of conductor tier 16 (not shown). Trenches 40 may taper laterally inward and/or outward in vertical cross-section (not shown). Thereafter and through trenches 40, sacrificial material 26 and sacrifice material 35 (neither being shown) have been replaced with conductive material 48 whereby sacrifice-material tier 42 and first tiers 22 collectively become conductive-material tiers 22 and 42. For example and in one embodiment, sacrificial material 26 and sacrifice material 35 (neither being shown) have been removed by being isotropically etched away through trenches 40 ideally selectively relative to the other exposed materials (e.g., using liquid or vapor H₃PO₄ as a primary etchant where materials 26 and 35 are silicon nitride and other materials comprise one or more oxides or polysilicon). Thereafter, conductive material 48 is formed in tiers 22 and 42 through trenches 40, and which is thereafter removed from trenches 40, thus forming individual conductive lines 29 (e.g., wordlines) and elevationally-extending strings 49 of individual transistors and/or memory cells 56 in stack 18. In one ideal embodiment, the replacing of materials 26 and 35 comprises etching such materials at the same time.

A thin insulative liner (e.g., Al₂O₃ and not shown) may be formed before forming conductive material 48. Approximate locations of transistors and/or memory cells 56 are indicated with a bracket in some figures and some with dashed outlines in some figures, with transistors and/or memory cells 56 being essentially ring-like or annular in the depicted example. Alternately, transistors and/or memory cells 56 may not be completely encircling relative to individual lower channel openings 25 such that each lower channel opening 25 may have two or more elevationally-extending strings 49 (e.g., multiple transistors and/or memory cells about individual channel openings in individual conductive tiers with perhaps multiple wordlines per channel opening in individual conductive tiers, and not shown). Conductive material 48 may be considered as having terminal ends 50 corresponding to control-gate regions 52 of individual transistors and/or memory cells 56. Control-gate regions 52 in the depicted embodiment comprise individual portions of individual conductive lines 29. Materials 30, 32, and 34 may be considered as a memory structure 65 that is laterally between control-gate region 52 and first channel material 36. In one embodiment and as shown with respect to the example “gate-last” processing, conductive material 48 of conductive tiers 22 is formed after forming channel openings 25 and/or trenches 40. Alternately, the conducting material of the conductive tiers may be formed before forming lower channel openings 25 and/or trenches 40 (not shown), for example with respect to “gate-first” processing.

A charge-blocking region (e.g., charge-blocking material 30) is between storage material 32 and individual control-gate regions 52. A charge block may have the following functions in a memory cell: In a program mode, the charge block may prevent charge carriers from passing out of the storage material (e.g., floating-gate material, charge-trapping material, etc.) toward the control gate, and in an erase mode the charge block may prevent charge carriers from flowing into the storage material from the control gate. Accordingly, a charge block may function to block charge migration between the control-gate region and the storage material of individual memory cells. An example charge-blocking region as shown comprises insulator material 30. By way of further examples, a charge-blocking region may comprise a laterally (e.g., radially) outer portion of the storage material (e.g., material 32) where such storage material is insulative (e.g., in the absence of any different-composition material between an insulative storage material 32 and conductive material 48). Regardless, as an additional example, an interface of a storage material and conductive material of a control gate may be sufficient to function as a charge-blocking region in the absence of any separate-composition-insulator material 30. Further, an interface of conductive material 48 with material 30 (when present) in combination with insulator material 30 may together function as a charge-blocking region, and as alternately or additionally may a laterally-outer region of an insulative storage material (e.g., a silicon nitride material 32). An example material 30 is one or more of silicon hafnium oxide and silicon dioxide.

Intervening material 57 has then been formed in trenches 40 and thereby laterally-between and longitudinally-along immediately-laterally-adjacent memory blocks 58. Intervening material 57 may provide lateral electrical isolation (insulation) between immediately-laterally-adjacent memory blocks. Such may include one or more of insulative, semiconductive, and conducting materials and, regardless, may facilitate conductive tiers 22 from shorting relative one another in a finished circuitry construction. Example insulative materials are one or more of SiO₂, Si₃N₄, and Al₂O₃. Intervening material 57 may include through array vias (not shown).

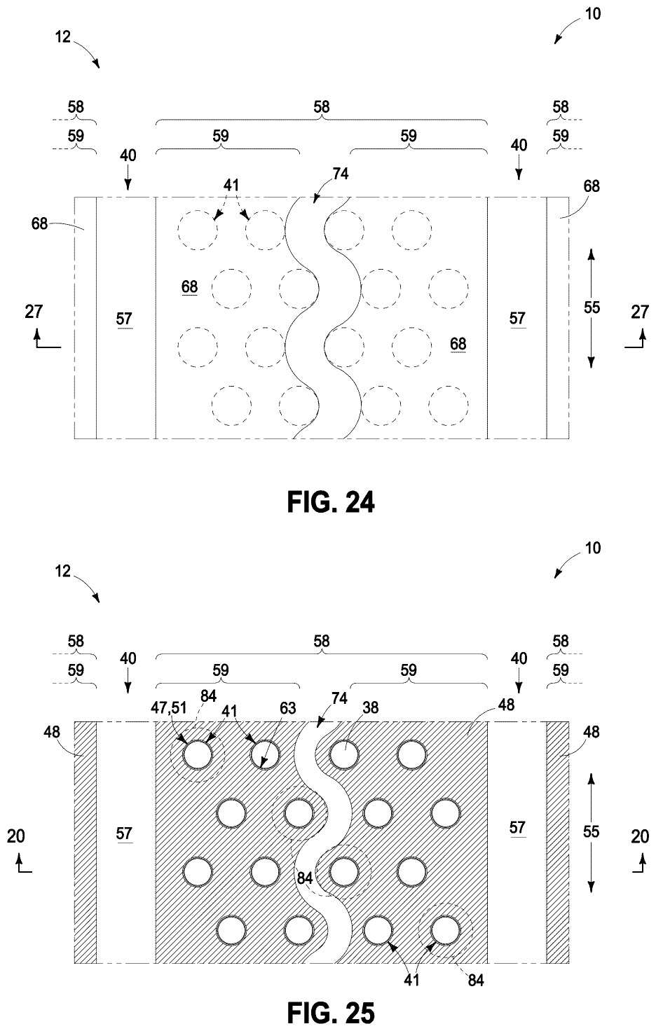

Referring to FIGS. 24-28, etching has been conducted through conductive material 48 in select-gate region 13 that extends laterally-between immediately-laterally-adjacent sub-blocks 59 that results from the replacing (e.g., forming sub-block trenches 74) to form select gates 60 of select-gate transistors 84 in select-gate region 13 in individual sub-blocks 59 operatively alongside second channel material 64 that is in select-gate region 13 in individual sub-blocks 59. Select gates 60 comprise conductive material 48 that is in conductive-material tier 42 and conductive material 48 that extends downwardly from conductive-material tier 42 to below conductive-material tier 42 alongside first channel material 36. In one embodiment, conductive material 48 and select gates 60 extend upwardly from conductive-material tier 42 to above conductive-material tier 42 and to have a top 69 that is below a bottom 70 of conducting metal material 66.

In one embodiment, gate insulator layer 51 is laterally-between select gates 60 and second channel material 64 and that extends laterally to be vertically-between second channel material 64 and select gates 60 directly under select gates 60. In one such embodiment and as shown, gate insulator layer 51 that is directly under the select gates has the greater vertical thickness T than lateral thickness L of gate insulator layer 51 that is laterally-between the select gates 60 and second channel material 64.

Any other attribute(s) or aspect(s) as shown and/or described herein with respect to other embodiments may be used in the embodiments shown and described with reference to the above embodiments.

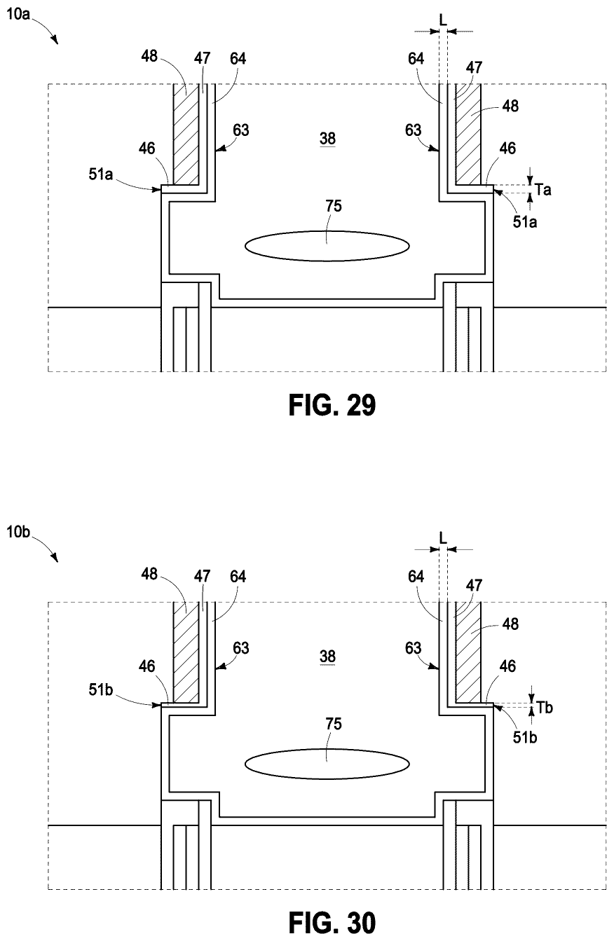

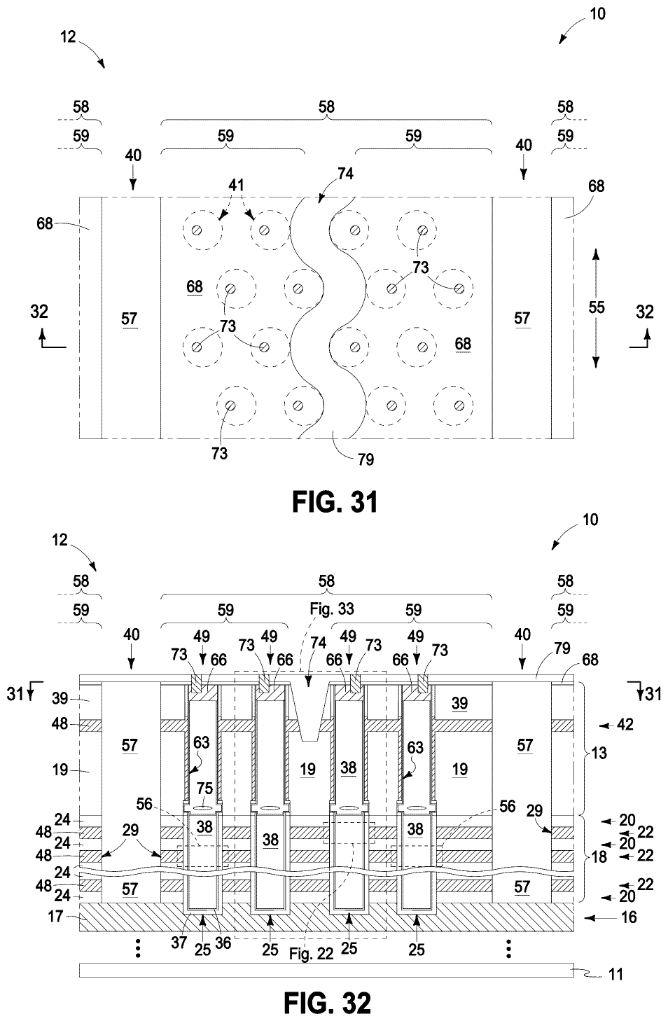

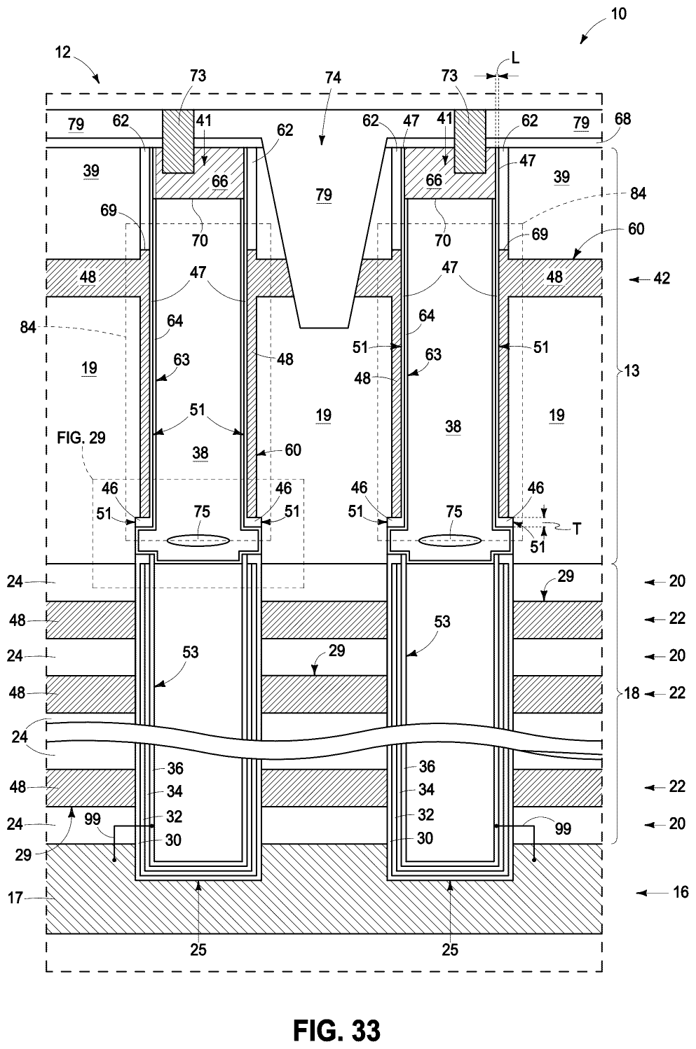

In another such embodiment, the gate insulator layer that is directly under the select gates has the same or less vertical thickness as the lateral thickness of the gate insulator layer that is laterally-between the select gates and the second channel material. FIG. 29 shows an alternate embodiment construction 10a where vertical thickness Ta of gate insulator layer 51a is equal to lateral thickness L of gate insulator layer 51a and FIG. 30 shows an alternate embodiment construction 10b where vertical thickness Tb of gate insulator layer 51b is less than lateral thickness L of gate insulator layer 51b. Like numerals from the above-described embodiments have been used where appropriate, with some construction differences being indicated with the suffix “a” and “b”, respectively, or with different numerals. Any other attribute(s) or aspect(s) as shown and/or described herein with respect to other embodiments may be used.

Referring to FIGS. 31-33, and in one embodiment, insulative material 79 (e.g., silicon dioxide) has been formed in sub-block trenches 74 and conductive vias 73 have been formed that directly electrically couple to conducting metal material 66 and thereby to first channel material 36. Conductive vias 73 would electrically connect with respective other circuitry components (e.g., digitlines and not shown) as would select gates 60 (such other circuitry not being shown) not material to the invention.

Heretofore, select gates are typically comprised of multiple (not shown) vertically-spaced tiers 42 of conductive material 48 that are shorted together. Further, more than one conductive via 73 is typically used per memory cell string 49 to directly electrically couple with an overlying digitline. Collectively, these can lead to one or more of the etching of the sub-block trenches etching into the memory-cell string structures, over or under etching of the sub-block trenches, and/or increased digitline capacitance. . . . Aspects of the invention may result in, although not require, a reduction or elimination of one or more of such phenomenon/phenomena.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, memory circuitry (e.g., 10) comprises a stack (e.g., 18) comprising vertically-alternating insulative tiers (e.g., 20) and conductive tiers (e.g., 22). The stack comprises laterally-spaced memory blocks (e.g., 58). The memory blocks individually comprise sub-blocks (e.g., 59) in an upper portion thereof. Strings (e.g., 49) of memory cells (e.g., 56) comprise channel-material strings (e.g., 53) that extend through the insulative tiers and the conductive tiers in the memory blocks. A conductive-material tier (e.g., 42) comprising conductive material (e.g., 48) is in the upper portions. The conductive material extends downwardly from the conductive-material tier to below the conductive-material tier. Select gates (e.g., 60) of select-gate transistors (e.g., 84) in individual of the sub-blocks are operatively alongside channel material (e.g., 64) of the select-gate transistors. The channel material of individual of the select-gate transistors is directly electrically coupled to the channel-material string there-below. The select gates comprise the conductive material of the conductive-material tier and the conductive material extending downwardly from the conductive-material tier to below the conductive-material tier alongside the channel material of the select-gate transistors. A gate insulator layer (e.g., 51) is laterally-between the select gates and the channel material of the select-gate transistors. The gate insulator layer extends laterally to be vertically-between the channel material and the select gates directly under the select gates. Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, modems, processor modules, and communication application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly Further, “extend(ing) elevationally”, horizontal. “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprising strings of memory cells comprises forming a stack and a select-gate region directly above the stack. The stack comprises memory blocks comprising first channel-material strings having sacrificial masses there-atop. The select-gate region comprises sub-blocks. Insulative material is atop and aside the sacrificial masses. An opening extends through the insulative material to individual of the sacrificial masses. Only a top region of the individual sacrificial masses is oxidized to form a gate oxide there-across. Etching is conducted through the gate oxide, a gate insulator material is formed in the opening directly against the gate oxide, remaining volume of the sacrificial masses is removed, and a second channel-material string is formed in the opening laterally-inward of the gate insulator material and that is directly electrically coupled to the first channel-material string there-below. Select gates are formed alongside second channel material of the second channel-material strings. The gate insulator material and the gate oxide comprise a continuous gate insulator layer that is laterally-between the select gates and the second channel material and that extends laterally to be vertically-between the second channel material and the select gates directly under the select gates.

In some embodiments, a method used in forming memory circuitry comprising strings of memory cells comprises forming a stack and a select-gate region directly above the stack. The stack comprises vertically-alternating different-composition first tiers and second tiers. The first tiers comprise sacrificial material. The stack comprising memory blocks comprises first channel-material strings. The select-gate region comprises sub-blocks. Insulative material in the select-gate region is above the first channel-material strings. Sacrifice material of a sacrifice-material tier is in the select-gate region atop the insulative material and extends laterally-between immediately-laterally-adjacent of the sub-blocks. The sacrifice material extends downwardly from the sacrifice-material tier to below the sacrifice-material tier alongside second channel material of second channel-material strings that are in the select-gate region. Individual of the second channel-material strings are directly electrically coupled to the first channel-material string there-below. The sacrificial material and the sacrifice material are replaced with conductive material whereby the sacrifice-material tier and the first tiers collectively become conductive-material tiers. conductive The material that extends laterally-between the immediately-laterally-adjacent sub-blocks that results from the replacing forms select gates in the select-gate region in individual of the sub-blocks operatively alongside the second channel material that is in the select-gate region in the individual sub-blocks is etched through. The select gates comprise the conductive material in the conductive-material tier and the conductive material extends downwardly from the conductive-material tier in the select-gate region to below the conductive-material tier alongside the second channel material.

In some embodiments, memory circuitry comprises a stack comprising vertically-alternating insulative tiers and conductive tiers. The stack comprises laterally-spaced memory blocks. The memory blocks individually comprise sub-blocks in an upper portion thereof. Strings of memory cells comprise channel-material strings that extend through the insulative tiers and the conductive tiers in the memory blocks. A conductive-material tier is included that comprises conductive material in the upper portions. The conductive material extends downwardly from the conductive-material tier to below the conductive-material tier. Select gates of select-gate transistors in individual of the sub-blocks are operatively alongside channel material of the select-gate transistors. The channel material of individual of the select-gate transistors is directly electrically coupled to the channel-material string there-below. The select gates comprise the conductive material of the conductive-material tier and the conductive material extends downwardly from the conductive-material tier to below the conductive-material tier alongside the channel material of the select-gate transistors. A gate insulator layer is laterally-between the select gates and the channel material of the select-gate transistors. The gate insulator layer extends laterally to be vertically-between the channel material and the select gates directly under the select gates.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry comprising strings of memory cells, comprising:
forming a stack and a select-gate region directly above the stack, the stack comprising memory blocks comprising first channel-material strings having sacrificial masses there-atop, the select-gate region comprising sub-blocks, insulative material being atop and aside the sacrificial masses, an opening extending through the insulative material to individual of the sacrificial masses;
oxidizing only a top region of the individual sacrificial masses to form a gate oxide there-across;
etching through the gate oxide, forming a gate insulator material in the opening directly against the gate oxide, removing remaining volume of the sacrificial masses, and forming a second channel-material string in the opening laterally-inward of the gate insulator material and that is directly electrically coupled to the first channel-material string there-below; and
forming select gates alongside second channel material of the second channel-material strings, the gate insulator material and the gate oxide comprise a continuous gate insulator layer that is laterally-between the select gates and the second channel material and that extends laterally to be vertically-between the second channel material and the select gates directly under the select gates.

2. The method of claim 1 wherein the gate insulator material is formed in the opening directly against the gate oxide before the removing.

3. The method of claim 1 wherein the opening at a top surface of the individual sacrificial masses is smaller in area than area of said top surface.

4. The method of claim 1 wherein the gate insulator layer that is directly under the select gates has the same or less vertical thickness as lateral thickness of the gate insulator layer that is laterally-between the select gates and the second channel material.

5. The memory circuitry of claim 4 wherein the vertical thickness is the same as the lateral thickness.

6. The memory circuitry of claim 4 wherein the vertical thickness is less than the lateral thickness.

7. The memory circuitry of claim 4 wherein the gate insulator layer that is directly under the select gates has greater vertical thickness than lateral thickness of the gate insulator layer that is laterally-between the select gates and the second channel material.

8. A method used in forming memory circuitry comprising strings of memory cells, comprising:
forming a stack and a select-gate region directly above the stack, the stack comprising vertically-alternating different-composition first tiers and second tiers, the first tiers comprising sacrificial material, the stack comprising memory blocks comprising first channel-material strings, the select-gate region comprising sub-blocks, insulative material in the select-gate region above the first channel-material strings, sacrifice material of a sacrifice-material tier in the select-gate region atop the insulative material and extending laterally-between immediately-laterally-adjacent of the sub-blocks, the sacrifice material extending downwardly from the sacrifice-material tier to below the sacrifice-material tier alongside second channel material of second channel-material strings that are in the select-gate region, individual of the second channel-material strings being directly electrically coupled to the first channel-material string there-below;
replacing the sacrificial material and the sacrifice material with conductive material whereby the sacrifice-material tier and the first tiers collectively become conductive-material tiers; and
etching through the conductive material that extends laterally-between the immediately-laterally-adjacent sub-blocks that results from the replacing to form select gates in the select-gate region in individual of the sub-blocks operatively alongside the second channel material that is in the select-gate region in the individual sub-blocks, the select gates comprising the conductive material in the conductive-material tier and the conductive material extending downwardly from the conductive-material tier in the select-gate region to below the conductive-material tier alongside the second channel material.

9. The method of claim 8 comprising covering the sacrifice material with insulating material prior to the replacing.

10. The method of claim 8 wherein the conductive material and the select gates extend upwardly from the conductive-material tier to above the conductive-material tier.

11. The method of claim 8 comprising conducting metal material in the select-gate region that is directly against the second channel material, the conductive material and the select gates that extend upwardly from the conductive-material tier to above the conductive-material tier having a top that is below a bottom of the conducting metal material that is below the top of the second channel material.

12. The method of claim 8 wherein a gate insulator layer is between the select gates and the second channel material and extends laterally to be directly under the select gates.

13. The method of claim 12 wherein the gate insulator layer extends upwardly to be above a top of the conductive-material tier.

14. The method of claim 8 wherein the replacing comprises etching the sacrificial material and the sacrifice material at the same time.

15. Memory circuitry comprising:
a stack comprising vertically-alternating insulative tiers and conductive tiers, the stack comprising laterally-spaced memory blocks, the memory blocks individually comprising sub-blocks in an upper portion thereof, strings of memory cells comprising channel-material strings that extend through the insulative tiers and the conductive tiers in the memory blocks;
a conductive-material tier comprising conductive material in the upper portions, the conductive material the extending downwardly from conductive-material tier to below the conductive-material tier;
select gates of select-gate transistors in individual of the sub-blocks operatively alongside channel material of the select-gate transistors, the channel material of individual of the select-gate transistors being directly electrically coupled to the channel-material string there-below, the select gates comprising the conductive material of the conductive-material tier and the conductive material extending downwardly from the conductive-material tier to below the conductive-material tier alongside the channel material of the select-gate transistors; and
a gate insulator layer that is laterally-between the select gates and the channel material of the select-gate transistors, the gate insulator layer extending laterally to be vertically-between the channel material and the select gates directly under the select gates.

16. The memory circuitry of claim 15 wherein the gate insulator layer that is directly under the select gates has the same or less vertical thickness as lateral thickness of the gate insulator layer that is laterally-between the select gates and the channel material of the select-gate transistors.

17. The memory circuitry of claim 16 wherein the vertical thickness is the same as the lateral thickness.

18. The memory circuitry of claim 16 wherein the vertical thickness is less than the lateral thickness.

19. The memory circuitry of claim 16 wherein the gate insulator layer that is laterally-between the select gates and the channel material of the select-gate transistors extends upwardly to be above a top of the conductive-material tier.

20. The memory circuitry of claim 16 wherein the gate insulator layer that is directly under the select gates has greater vertical thickness than lateral thickness of the gate insulator layer that is laterally-between the select gates and the channel material of the select-gate transistors.

21. The memory circuitry of claim 15 wherein the conductive material and the select gates extend upwardly from the conductive-material tier to above the conductive-material tier.

22. The memory circuitry of claim 21 comprising conducting metal material above the select gates that is directly against the channel material, the conductive material and the select gates that extend upwardly from the conductive-material tier to above the conductive-material tier having a top that is below a bottom of the conducting metal material that is below the top of the channel material of the select-gate transistors.

23. The memory circuitry of claim 21 wherein the gate insulator layer that is directly under the select gates has greater vertical thickness than lateral thickness of the gate insulator layer that is laterally-between the select gates and the channel material of the select-gate transistors.
